(19) United States
(12) Patent Application Publication
(10) Pub. No.: US 2020/0019004 A1
(43) Pub. Date: Jan. 16, 2020

(54) LIQUID CRYSTAL DISPLAY DEVICE FOR HEAD-MOUNTED DISPLAY, AND HEAD-MOUNTED DISPLAY

(71) Applicant: Sharp Kabushiki Kaisha, Sakai City, Osaka (JP)

(72) Inventors: Seiichi UCHIDA, Sakai City (JP); Kuniaki OKADA, Sakai City (JP)

(21) Appl. No.: 16/485,489

(22) PCT Filed: Feb. 6, 2018
(86) PCT No.: PCT/JP2018/004073

§ 371 Date: Aug. 13, 2019

(30) Foreign Application Priority Data
Feb. 15, 2017 (JP) 2017-025950

(51) Int. Cl. G02F 1/1368; G02B 27/01; G02F 1/1339; G02F 1/1335; H01L 27/12

(52) U.S. Cl. CPC G02F 1/1368; G02B 27/0101; G02B 2027/0178; G02F 1/133512; H01L 27/1225; G02F 1/13394

(57) ABSTRACT

A liquid crystal display device for head-mounted displays includes a first substrate, a second substrate, a liquid crystal layer, and a plurality of columnar spacers. The first substrate has a TFT provided in each pixel, a plurality of gate bus lines, and a plurality of source bus lines. The TFT includes an oxide semiconductor layer. Each columnar spacer is in contact with both of the first substrate and the second substrate. The second substrate includes a light shielding layer, the light shielding layer including first light shielding portions overlapping the gate bus lines or the source bus lines and second light shielding portions respectively overlapping the columnar spacers. Each columnar spacer is placed in one of the plurality of blue pixels. The second light shielding portions of the light shielding layer are placed so that, in those blue pixels in which the second light shielding portions exist, a decrease in aperture ratio ascribable to the second light shielding portions is 30% or less.

### TECHNICAL FIELD

The present invention relates to a liquid crystal display device, and more particularly to a liquid crystal display device that includes thin film transistors (oxide semiconductor TFTs) having an oxide semiconductor layer as an active layer. The present invention also relates to a head-mounted display that includes such a liquid crystal display device in a display section.

### BACKGROUND ART

An active matrix substrate for use in a liquid crystal display device or the like includes a switching element, e.g., a thin film transistor (Thin Film Transistor; hereinafter “TFT”), for each pixel. As such switching elements, TFTs in which an oxide semiconductor layer is used as the active layer (hereinafter referred to as “oxide semiconductor TFTs”) are known. Patent Document 1 discloses a liquid crystal display apparatus in which InGaZnO (an oxide of indium, gallium, and zinc) is used as the active layer of each TFT.

An oxide semiconductor TFT is capable of operating more rapidly than an amorphous silicon TFT. Moreover, an oxide semiconductor film is formed through a simpler process than that used for a polycrystalline silicon film, and therefore is applicable to devices which require a large geometric area. Therefore, oxide semiconductor TFTs are expected to be high-performance active elements that can be produced with fewer production steps and less production cost.

Moreover, an oxide semiconductor has a high mobility; therefore, even if downsized relative to conventional amorphous silicon TFTs, it can still attain a similar level of performance or higher. Therefore, when the active matrix substrate of a liquid crystal display device is produced by using oxide semiconductor TFTs, the percentage footprint of the TFT within the pixel can be reduced, thereby providing for an improved pixel aperture ratio. This enables bright displaying, even if the light amount of the backlight is kept low, such that low power consumption can be achieved.

### CITATION LIST

### Patent Literature

[Patent Document 1] Japanese Laid-Open Patent Publication No. 2012-134475

[Patent Document 2] Japanese Laid-Open Patent Publication No. 2011-66375

[Patent Document 3] Japanese Laid-Open Patent Publication No. 2006-126855

### SUMMARY OF INVENTION

### Technical Problem

As described above, using oxide semiconductor TFTs provides an improved aperture ratio as compared to using amorphous silicon TFTs. In recent years, however, liquid crystal display devices are becoming increasingly higher in definition, and thus further improvements in aperture ratio are being desired.

However, for the following reasons, further improvements in the aperture ratio of a liquid crystal display device including oxide semiconductor TFTs are difficult to make.

The TFT characteristics of an oxide semiconductor TFT may become deteriorated through light irradiation (see Patent Document 2). Specifically, a shift in the minus direction of the threshold voltage may occur. Therefore, in a liquid crystal display device that includes oxide semiconductor TFTs, a black matrix (light shielding layer) provided at the side of a counter substrate (which in itself is opposed to an active matrix substrate) includes regions overlapping the oxide semiconductor TFTs, such that the oxide semiconductor TFTs are shaded by these regions (TFT light shielding portions). These TFT light shielding portions hinder further improvements in the aperture ratio from being made.

Moreover, in a liquid crystal display device, in order to define the thickness (cell gap) of the liquid crystal layer, a plurality of columnar spacers are provided between the active matrix substrate and the counter substrate. Since the alignment of the liquid crystal molecules is disturbed in the neighborhood of each columnar spacer, the black matrix includes portions to shade the columnar spacers and their neighborhoods (spacer light-shielding portions). These spacer light-shielding portions also hinder further improvements in the aperture ratio from being made. If the number of columnar spacers is increased in order to provide pressure resistance, the number of spacer light-shielding portions will also increase accordingly, so that the decrease in the aperture ratio caused by the spacer light-shielding portions will become more outstanding.

Patent Document 3 discloses a construction which may prevent a decrease in the aperture ratio caused by a low accuracy of mutual positioning between the active matrix substrate and the counter substrate (i.e., a misalignment during attachment). In the construction disclosed in Patent Document 3, the color filters are provided not on the counter substrate side, but on the active matrix substrate side (called a color-filter-on-array structure). Moreover, the TFT of each pixel is shaded by a red color filter, and thus a black matrix is omitted. In the construction of Patent Document 3, regarding the green pixels and the blue pixels, it is necessary to respectively form color filters of different colors within one pixel (i.e., a green color filter and a red color filter in a green pixel, and a blue color filter and a red color filter in a blue pixel). However, when the displaying definition is very high (i.e., the pixel size is very small), it will be difficult to apply such fine processing to the color filters.

The present invention has been made in view of the above problems, and an objective thereof is to improve the aperture ratio of a liquid crystal display device that includes oxide semiconductor TFTs.

### Solution to Problem

A liquid crystal display device for head-mounted displays according to an embodiment of the present invention is a liquid crystal display device for head-mounted displays comprising: a first substrate; a second substrate opposing the first substrate; a liquid crystal layer provided between the first substrate and the second substrate; and a plurality of columnar spacers provided between the first substrate and the second substrate, the plurality of columnar spacers defining a thickness of the liquid crystal layer, the liquid crystal display device having a plurality of pixels arranged in a matrix array including a plurality of rows and a plurality of columns, wherein, the plurality of pixels include a plurality of red pixels, a plurality of green pixels, and a plurality of blue pixels; the first substrate has a thin film transistor provided in each of the plurality of pixels, a plurality of gate bus lines extending along one of a row direction and a column direction, and a plurality of source bus lines extending along another of the row direction and the column direction; each thin film transistor includes an oxide semiconductor layer; each of the plurality of columnar spacers is in contact with both of the first substrate and the second substrate, such that the plurality of columnar spacers do not include any columnar spacers that are in contact with only one of the first substrate and the second substrate; the second substrate includes a light shielding layer, the light shielding layer including first light shielding portions respectively overlapping the plurality of gate bus lines or the plurality of source bus lines, and a second light shielding portions respectively overlapping the plurality of columnar spacers; each of the plurality of columnar spacers is placed in one of the plurality of blue pixels; and the second light shielding portions of the light shielding layer are placed so that, in those blue pixels in which the second light shielding portions exist, a decrease in aperture ratio ascribable to the second light shielding portions is 30% or less.

In one embodiment, the plurality of columnar spacers are placed in a subset of blue pixels among the plurality of blue pixels.

In one embodiment, the plurality of columnar spacers are placed so as to overlap the thin film transistors in the subset of blue pixels.

In one embodiment, the light shielding layer further includes third light shielding portions that are substantially identical in shape to the second light shielding portions, the third light shielding portions not overlapping the plurality of columnar spacers.

In one embodiment, the second light shielding portions and the third light shielding portions of the light shielding layer are placed so that the plurality of blue pixels have substantially a same aperture ratio.

In one embodiment, the plurality of gate bus lines extend along the row direction; the plurality of source bus lines extend along the column direction; the first light shielding portions respectively overlap the plurality of source bus lines; the plurality of pixels are arranged so that a plurality of red pixel columns extending along the column direction, a plurality of green pixel columns extending along the column direction, and a plurality of blue pixel columns extending along the column direction are defined; each of the second light shielding portions and the third light shielding portions is formed astride two blue pixels which adjoin each other along the column direction; and either the respective second light shielding portion or the respective third light shielding portion is located at one end portion or another end portion of each of the plurality of blue pixels along the column direction.

In one embodiment, a density of placement of the plurality of columnar spacers is not more than 12 pieces/mm².

In one embodiment, a density of placement of the plurality of columnar spacers is more than 12 pieces/mm² but not more than 120 pieces/mm².

In one embodiment, the first substrate further includes a pixel electrode provided in each of the plurality of pixels, the pixel electrode being electrically connected to a drain electrode of the thin film transistor; and the drain electrode is a transparent drain electrode being made of a same transparent electrically conductive film as the pixel electrode and extending from the pixel electrode.

In one embodiment, the first substrate includes an inorganic insulating layer at least covering the oxide semiconductor layers of the thin film transistors; and the first substrate does not include an organic insulating layer between the inorganic insulating layer and the pixel electrodes.

In one embodiment, the oxide semiconductor layer comprises an In—Ga—Zn—O based semiconductor.

In one embodiment, the In—Ga—Zn—O based semiconductor includes a crystalline portion.

A head-mounted display according to an embodiment of the present invention, is a head-mounted display comprising a display section placed so as to be in front of both eyes of a user when worn, wherein the display section includes a liquid crystal display device having any of the above constructions.

### Advantageous Effects of Invention

According to an embodiment of the present invention, the aperture ratio of a liquid crystal display device that includes oxide semiconductor TFTs can be improved.

### BRIEF DESCRIPTION OF DRAWINGS

FIG. 1 is a plan view schematically showing a liquid crystal display device 100 according to an embodiment of the present invention.

FIG. 2 is a cross-sectional view schematically showing a liquid crystal display device 100 according to an embodiment of the present invention, showing a cross section taken along line 2A-2A′ in FIG. 1.

FIG. 3 is a plan view showing a liquid crystal display device 900 according to Comparative Example.

FIG. 4 is a graph showing a result of an experiment of evaluating visual recognition of pixels (blue pixels B) in which columnar spacers 40 are placed.

FIGS. 5(a) through (e) are step-by-step cross-sectional views illustrating production steps of a TFT substrate 10, showing a cross section corresponding to FIG. 2.

FIGS. 6(a) through (c) are step-by-step cross-sectional views illustrating production steps of the TFT substrate 10, showing a cross section corresponding to FIG. 2.

FIGS. 7(a) through (c) are step-by-step cross-sectional views illustrating production steps of a counter substrate 20, showing a cross section corresponding to FIG. 2.

FIG. 8(a) is a plan view schematically showing the liquid crystal display device 100, and (b) is a plan view schematically showing another liquid crystal display device 200 according to an embodiment of the present invention.

FIG. 9 is a plan view schematically showing still another liquid crystal display device 300 according to an embodiment of the present invention.

FIG. 10 is a diagram showing a pixel arrangement for a liquid crystal display device of a lateral stripe arrangement.

FIG. 11 is a plan view schematically showing another TFT substrate 10A for use in a liquid crystal display device according to an embodiment of the present invention.

FIG. 12 is a cross-sectional view of a crystalline silicon TFT 710A and an oxide semiconductor TFT 710B on the TFT substrate 10A.

FIG. 13(a) is a diagram showing a schematic construction of a head-mounted display 500, and (b) is a diagram showing how the head-mounted display 500 may be worn by a user U.

### DESCRIPTION OF EMBODIMENTS

Hereinafter, with reference to the drawings, embodiments of the present invention will be described. Note that the present invention is not to be limited to the following embodiments.

### Embodiment 1

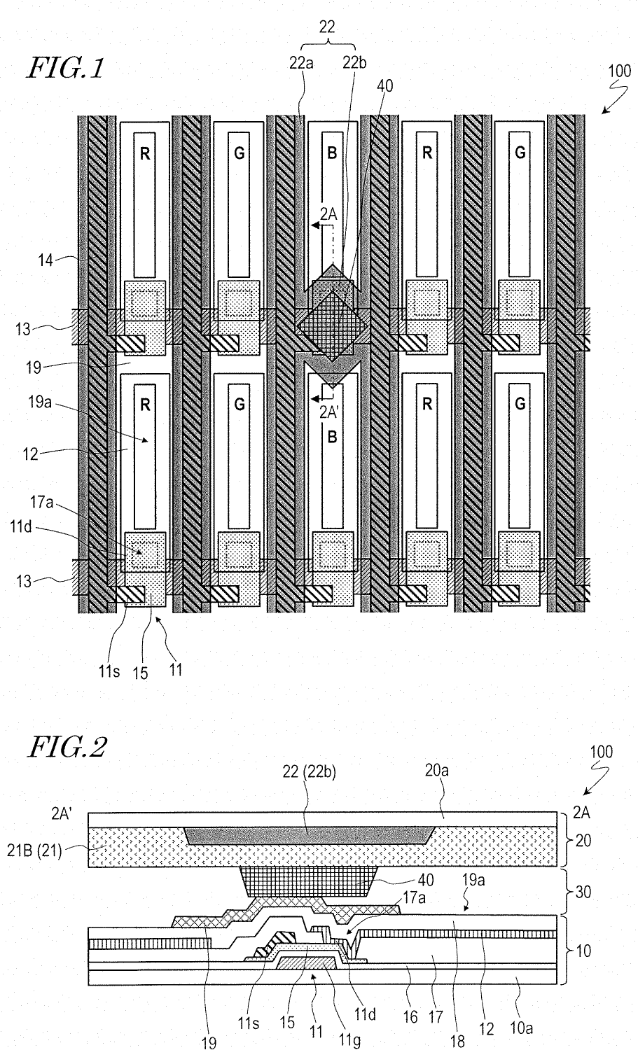

With reference to FIG. 1 and FIG. 2, a liquid crystal display device 100 according to the present embodiment will be described. The liquid crystal display device 100 is a liquid crystal display device for head-mounted displays. In other words, the liquid crystal display device 100 is suitably used as a display section of a head-mounted display.

FIG. 1 is a plan view schematically showing the liquid crystal display device 100. FIG. 2 is a cross-sectional view schematically showing the liquid crystal display device 100, showing a cross section taken along line 2A-2A′ in FIG. 1. Although a liquid crystal display device 100 of the FFS (Fringe Field Switching) mode is illustrated herein, the display mode is not limited to the FFS mode. As the display mode, various known display modes such as the TN (Twisted Nematic) mode or the VA (Vertical Alignment) mode can be used.

As shown in FIG. 2, the liquid crystal display device 100 includes an active matrix substrate (hereinafter referred to as the “TFT substrate”) 10, a counter substrate opposed to the TFT substrate 10 (also referred to the “color filter substrate”) 20, and a liquid crystal layer 30 provided between the TFT substrate 10 and the counter substrate 20. The liquid crystal display device 100 further includes a plurality of columnar spacers 40 provided between the TFT substrate 10 and the counter substrate 20. The plurality of columnar spacers 40 define the thickness (cell gap) of the liquid crystal layer 30.

Moreover, as shown in FIG. 1, the liquid crystal display device 100 has a plurality of pixels arranged in a matrix array, including a plurality of rows and a plurality of columns. The plurality of pixels include a plurality of red pixels R, a plurality of green pixels G, and a plurality of blue pixels B. In the example shown in FIG. 1, the plurality of pixels are arranged so that a plurality of red pixel columns extending along the column direction, a plurality of green pixel columns extending along the column direction, and a plurality of blue pixel columns extending along the column direction are defined (so-called “stripe arrangement”).

The TFT substrate 10 has a thin film transistor (TFT) 11 and a pixel electrode 12 provided in each pixel, a plurality of gate bus lines (scanning lines) 13 extending along a row direction, and a plurality of source bus lines (signal lines) 14 extending along a column direction.

Each TFT 11 includes an oxide semiconductor layer 15 as an active layer. In other words, the TFTs 11 are oxide semiconductor TFTs.

Each TFT 11 further includes a gate electrode 11g, a source electrode lls, and a drain electrode 11d. The gate electrode llg is electrically connected to a gate bus line 13, so as to receive a gate signal (scanning signal) supplied from the gate bus line 13. In the example shown in the figures, a portion of a gate bus line 13 (i.e., a region overlapping the oxide semiconductor layer 15) functions as the gate electrode 11g. The source electrode lls is electrically connected to a source bus line 14, so as to receive a source signal (displaying signal) supplied from the source bus line 14. In the example shown in the figures, the source electrode 11s extends in a manner of branching out from the source bus line 14. The drain electrode 11d is electrically connected to the pixel electrode 12.

The region of the oxide semiconductor layer 15 which is in contact with the source electrode 11s is called a “source region”, whereas the region thereof which is in contact with the drain electrode 11d is called a “drain region”. The region of the oxide semiconductor layer 15 which overlaps the gate electrode 11g and which is located between the source region and the drain region is called a “channel region”.

The TFTs 11 are supported by a transparent insulative substrate (e.g. a glass substrate) 10a. On the surface of the insulative substrate 10a that is closer to the liquid crystal layer 30, the gate electrodes 11g and the gate bus lines 13 are provided, with a gate insulating layer 16 being provided so as to cover the gate electrodes 11g and the gate bus lines 13.

On the gate insulating layer 16, the oxide semiconductor layer 15, the source electrodes 11s, and the source bus lines 14 are provided. Each source electrode 11s is formed so as to be in contact with the upper face of a source region of the oxide semiconductor layer 15.

An inorganic insulating layer 17 is provided so as to cover the oxide semiconductor layer 15, the source electrodes 11s and the source bus lines 14. The pixel electrodes 12 are provided on the inorganic insulating layer 17. No organic insulating layer is provided between the inorganic insulating layer 17 and the pixel electrodes 12. In the present embodiment, a portion which is made of the same transparent electrically conductive film as the pixel electrode 12 and which extends from the pixel electrode 12 functions as the drain electrode 11d. That is, the drain electrode 11d is transparent. In the present specification, such a drain electrode 11d is also referred to as a “transparent drain electrode”, and the contact structure including the transparent drain electrode 11d is referred to as a “transparent contact structure”. In a contact hole 17a that is made in the inorganic insulating layer 17, the drain electrode 11d is in contact with the upper face of the drain region of the oxide semiconductor layer 15.

A dielectric layer 18 is provided so as to cover the pixel electrodes 12. On the dielectric layer 18, a common electrode 19 is provided. In a region corresponding to each pixel, the common electrode 19 has at least one (e.g., one in the example shown in FIG. 1) slit 19a. A storage capacitor is constituted by the pixel electrode 12 and common electrode 19 and the dielectric layer 18 located therebetween.

The counter substrate 20 has a color filter layer 21 and a light shielding layer (black matrix) 22. The color filter layer 21 includes red color filters, green color filters, and blue color filters (with a blue color filter 21B being shown in FIG. 2). The color filter layer 21 and the light shielding layer 22 are supported by a transparent insulative substrate (e.g., glass substrate) 20a.

The red color filters, the green color filters, and the blue color filters extend along the column direction. The red color filters, the green color filters, and the blue color filters are formed respectively corresponding to the red pixel columns, the green pixel columns, and the blue pixel columns.

As shown in FIG. 1, the light shielding layer 22 includes first light shielding portions 22a overlapping the respective source bus lines 14 and second light shielding portions 22b overlapping the respective columnar spacers 40.

The liquid crystal layer 30 is a horizontal alignment type. On the surfaces of the TFT substrate 10 and the counter substrate 20 that are closer to the liquid crystal layer 30, horizontal alignment films (not shown herein) are respectively formed. The horizontal alignment films possess an alignment regulating force that causes liquid crystal molecules in the liquid crystal layer 30 to be aligned substantially in parallel to its surface.

The plurality of columnar spacers 40 are provided on the color filter layer 21. The plurality of columnar spacers 40 are made of a photosensitive resin material, for example.

As shown in FIG. 2, each of the plurality of columnar spacers 40 is in contact with both of the TFT substrate 10 and the counter substrate 20. In other words, the plurality of columnar spacers 40 do not include any columnar spacers that are in contact with only one of the TFT substrate 10 and the counter substrate 20 (i.e., only the counter substrate 20).

In a generic liquid crystal display device (liquid crystal panel), two kinds of columnar spacers of mutually different heights may be provided. The comparatively taller columnar spacers are referred to as “main spacers”, whereas the comparatively shorter columnar spacers are referred to as “subspacers”. While the main spacers are in contact with both of the TFT substrate and the counter substrate, the subspacers are in contact with only one of the substrates (i.e., the counter substrate). However, when the liquid crystal panel is pressed, the subspacers will also be in contact with both substrates. Therefore, by increasing the number of subspacers, an improved pressure resistance can be obtained. In the liquid crystal display device 100 according to the present embodiment, no columnar spacers corresponding to “subspacers” are provided, while only columnar spacers 40 corresponding to “main spacers” are provided.

In the present embodiment, each of the plurality of columnar spacers 40 is placed in one of the plurality of blue pixels B. That is, the plurality of columnar spacers 40 do not include any columnar spacers that are placed in red pixels R or green pixels G. In the construction illustrated in FIG. 1, the plurality of columnar spacers 40 are placed in a subset of blue pixels B among the plurality of blue pixels B, so as to overlap the TFTs 11 in the subset of blue pixels B. In other words, the blue pixels B in the display region include: blue pixels B having the columnar spacers 40 placed therein; and blue pixels B not having any columnar spacers 40 placed therein.

Furthermore, in the present embodiment, the second light shielding portions 22b of the light shielding layer 22 are placed so that (i.e., formed in a size such that) a decrease in aperture ratio ascribable to the second light shielding portions 22b in those blue pixels B in which the second light shielding portions 22b exist (i.e., a relative decrease in aperture ratio as compared to those blue pixels B in which the second light shielding portions 22b do not exist) is 30% or less.

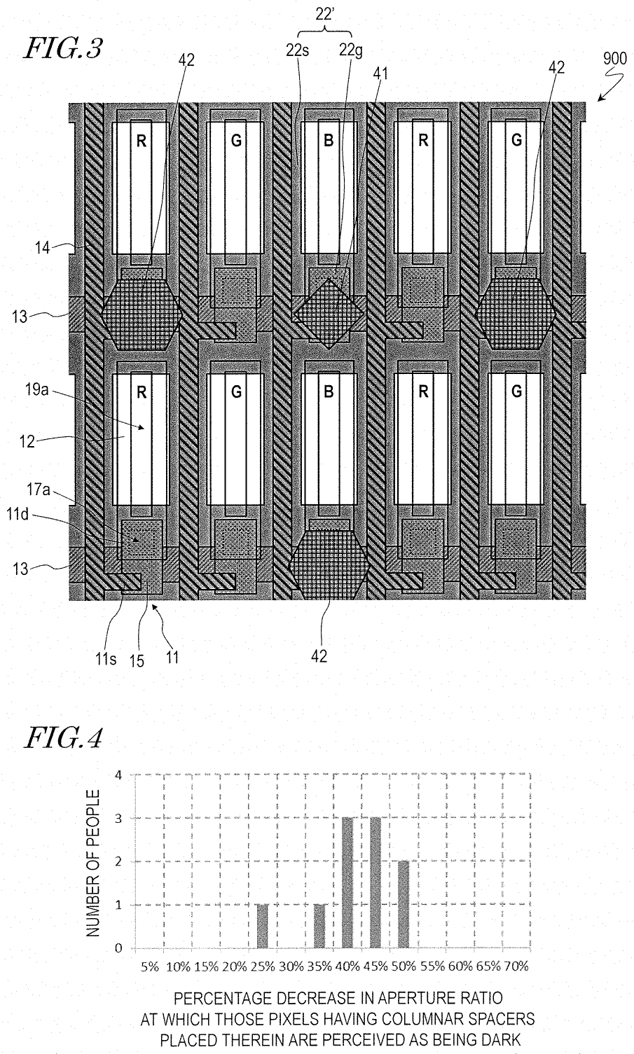

With the aforementioned construction, the liquid crystal display device 100 of the present embodiment is able to provide an improved aperture ratio. Hereinafter, the reasons thereof will be described with reference also to FIG. 3. FIG. 3 is a plan view showing a liquid crystal display device 900 according to Comparative Example. In FIG. 3, those constituent elements which are substantially identical to constituent elements of the liquid crystal display device 100 are denoted by identical reference numerals.

As shown in FIG. 3, the liquid crystal display device 900 of Comparative Example differs from the liquid crystal display device 100 in that it includes two kinds of columnar spacers 41 and 42 of mutually different heights. Regarding the two kinds of columnar spacers 41 and 42, the taller columnar spacers (main spacers) 41 are in contact with both of the TFT substrate and the counter substrate. On the other hand, the shorter columnar spacers (subspacers) 42 are in contact with only the counter substrate (i.e., not in contact with the TFT substrate). There are more subspacers 42 than there are main spacers 41. The main spacers 41 and the subspacers 42 are placed so as to overlap the TFTs 11 of a subset of pixels among the plurality of pixels in the display region.

Moreover, as shown in FIG. 3, a light shielding layer 22′ of the liquid crystal display device 900 of Comparative Example includes source light-shielding portions 22s extending along the column direction and gate light-shielding portions 22g extending along the row direction. The source light-shielding portions 22s overlap the source bus lines 14. The gate light-shielding portions 22g shade the main spacers 41 and any neighboring regions, the subspacers 42 and any neighboring regions, and the TFTs 11.

Generic liquid crystal display devices may find themselves in applications (e.g., touch screen panels) requiring a high pressure resistance. As in the liquid crystal display device 900 of Comparative Example, by providing two kinds of columnar spacers 41 and 42 of mutually different heights, such that there are more subspacers 42, a sufficiently high pressure resistance can be realized. However, as has already been described, the columnar spacers 41 and 42 and any neighboring regions need to be shaded. Therefore, placing the large number of subspacers 42 makes it necessary to correspondingly increase the geometric area of the light shielding layer 22′, thus resulting in a lower aperture ratio.

Moreover, when the TFTs 11 are irradiated with external light, the TFT characteristics will be deteriorated; therefore, those TFTs 11 which do not overlap the columnar spacers 41 and 42 also need to be shaded. This also is a cause for a lower aperture ratio.

The liquid crystal display device 100 of the present embodiment is for use in head-mounted displays; in head-mounted displays, any method of use where the liquid crystal panel would be pressed does not need to be considered. Thus, the pressure resistance may be low, and for this reason the plurality of columnar spacers 40 do not include any subspacers. Accordingly, the light shielding layer 22 does not need any portions to shade the subspacers and neighborhoods thereof (i.e., the geometric area of the light shielding layer 22 can be greatly reduced), whereby the aperture ratio can be improved correspondingly.

Moreover, in a head-mounted display, external light will hardly be incident on the liquid crystal panel during use, and thus there is no need to shade the TFTs. Therefore, the light shielding layer 22 of the liquid crystal display device 100 does not need to include any portions to shade the TFTs 11 of those pixels in which the columnar spacers 40 are not provided, whereby the aperture ratio can be further improved correspondingly.

Table 1 below shows an aperture ratio (an aperture ratio across the entire display region) in a high-definition liquid crystal panel which is contemplated to be a head-mounted display, in the case where the construction of the liquid crystal display device 900 of Comparative Example is adopted, and in the case where the construction of the liquid crystal display device 100 of the present embodiment is adopted.

TABLE 1
resolution: 1000 ppi
pixel size: 8.4 μm × 25.2 μm

| | aperture ratio |
|---|---|
| Comparative Example | 26% |
| Embodiment 1 | 37% |

As shown in Table 1, the aperture ratio in the case of adopting the construction of Comparative Example is 26%, while the aperture ratio in the case of adopting the construction of the present embodiment is 37%. Therefore, with the construction of the present embodiment, the aperture ratio can be improved by 42% relative to the construction of Comparative Example.

In the present embodiment, the regions of the subset of pixels in which the columnar spacers 40 are provided are shaded by the second light shielding portions 22b of the light shielding layer 22. As a result, those pixels in which the second light shielding portions 22b exist will be darker than those pixels in which the second light shielding portions 22b do not exist, because of a decreased aperture ratio, possibly being perceived as dark pixels. However, as in the present embodiment, when the columnar spacers 40 are placed only in the blue pixels B, which are hard to be perceived by the human eyes, those pixels in which the second light shielding portions 22b exist are less likely to be perceived as dark pixels. Moreover, by ensuring that a decrease in aperture ratio ascribable to the second light shielding portions 22b in those blue pixels B in which the second light shielding portions 22b exist is 30% or less, those pixels in which the second light shielding portions 22b exist can be made even harder to be perceived.

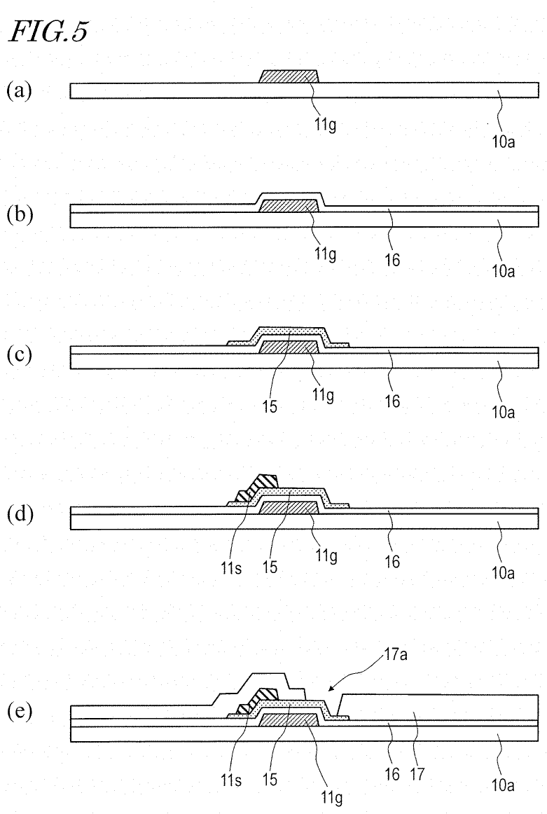

FIG. 4 shows a result of an experiment of evaluating visual recognition of pixels (blue pixels B) in which the columnar spacers 40 are placed. FIG. 4 is a graph where the horizontal axis denotes a percentage decrease in aperture ratio beyond which those pixels having the columnar spacers 40 placed therein will be perceived as being dark, while the vertical axis denotes the number of people.

FIG. 4 indicates that, as the percentage decrease in aperture ratio exceeds 30% (and in particular 35%), the number of people who perceive those pixels in which the columnar spacers 40 are placed as being dark will increase. Thus it can be seen that, by ensuring that the percentage decrease in aperture ratio, i.e., a decrease in aperture ratio ascribable to the second light shielding portions 22b, is 30% or less, those blue pixels B in which the second light shielding portions 22b exist become less likely to be perceived as dark pixels.

As described above, according to an embodiment of the present invention, the aperture ratio of a liquid crystal display device that includes oxide semiconductor TFTs can be improved. Moreover, unlike in the construction disclosed in Patent Document 3, the liquid crystal display device 100 of the present embodiment makes it unnecessary to respectively form color filters of different colors within one pixel; therefore, it is easy to form the color filter layer 21 even in super high-definition pixels.

Note that, as has already been described, oxide semiconductor TFTs are advantageous in terms of increasing the aperture ratio and increasing the definition, because they can be downsized relative to amorphous silicon TFTs. Furthermore, as compared also to low-temperature polysilicon TFTs, oxide semiconductor TFTs are advantageous in terms of increasing the aperture ratio and increasing the definition; the reason is that oxide semiconductor TFTs have smaller leak currents than do low-temperature polysilicon TFTs, and thus there is no need to provide a structure (e.g., a dual gate structure) for suppressing leak currents. Therefore, by not only adopting the construction of the present embodiment, but also using oxide semiconductor TFTs as the TFTs, further increases in the definition and the aperture ratio can be made.

As has already been described, in a head-mounted display, any method of use where the liquid crystal panel would be pressed does not need to be considered. Therefore, the density of placement of the plurality of columnar spacers 40 may be on a similar level to the density of placement of the main spacers in a conventionally-available generic liquid crystal display device, e.g., 12 pieces/mm² or less.

Note that the specific structure of the TFTs 11 being oxide semiconductor TFTs is not limited to what is illustrated herein. The TFTs 11 may be bottom-gate types as illustrated, or top-gate types.

As in the present embodiment, when transparent drain electrodes are used as the drain electrodes 11d (i.e., a transparent contact structure is adopted), further improves in the aperture ratio can be made. Also in the present embodiment, no organic insulating layer is provided upon the inorganic insulating layer 17; therefore, in order to electrically connect the pixel electrodes 12 and the TFTs 11, contact holes 17a may be formed only in the inorganic insulating layer 17. This allows the size (geometric area) of the contact portion to be reduced. Note that the drain electrodes 11d do not need to be transparent drain electrodes (e.g., they may be made of the same electrically conductive film as the source electrodes 11s ), and some organic insulating layer may be formed upon the inorganic insulating layer 17 (i.e., between the inorganic insulating layer 17 and the pixel electrodes 12).

Although FIG. 1 illustrates an example where the shape of each columnar spacer 40 as viewed from the normal direction of the display surface is a substantial square (substantial rhombus), the shape of the columnar spacers 40 is not limited thereto; various shapes (e.g., substantially circular or substantially hexagonal) may be used.

[Production Method]

An exemplary production method of the liquid crystal display device 100 will be described.

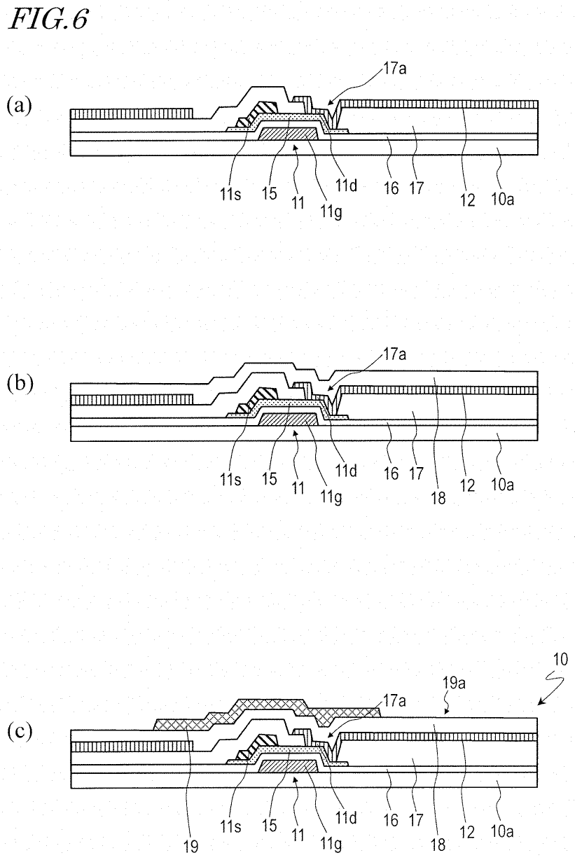

First, with reference to FIG. 5 and FIG. 6, a method of producing the TFT substrate 10 will be described. FIGS. 5(a) through (e) and FIGS. 6(a) through (c) are step-by-step cross-sectional views illustrating production steps of the TFT substrate 10, showing a cross section corresponding to FIG. 2.

First, as shown in FIG. 5(a), an electrically conductive film is deposited on an insulative substrate (e.g., a glass substrate) 10a, and this electrically conductive film is patterned by using a photolithography process, thereby forming gate electrodes 11g and gate bus lines 13. The gate electrodes 11g and the gate bus lines 13 have a multilayer structure in which a TaN layer having a thickness of 30 nm and a W layer having a thickness of 300 nm are stacked in this order, for example.

Next, as shown in FIG. 5(b), a gate insulating layer 16 is formed so as to cover the gate electrodes 11g and the gate bus lines 13. The gate insulating layer 16 has a multilayer structure in which an SiNx layer having a thickness of 325 nm and an SiO₂ layer having a thickness of 50 nm are stacked in this order, for example.

Then, as shown in FIG. 5(c), an oxide semiconductor film is deposited on the gate insulating layer 16, and this oxide semiconductor film is patterned by using a photolithography process, thereby forming an oxide semiconductor layer 15. The oxide semiconductor layer 15 is an In—Ga—Zn—O based semiconductor layer having a thickness of 50 nm, for example.

Thereafter, as shown in FIG. 5(d), an electrically conductive film is deposited, and this electrically conductive film is patterned by using a photolithography process, thereby forming source electrodes 11s and source bus lines 14. The source electrodes 11s and the source bus lines 14 have a multilayer structure in which a Ti layer having a thickness of 30 nm, an Al layer having a thickness of 200 nm, and a Ti layer having a thickness of 100 nm are stacked in this order, for example.

Next, as shown in FIG. 5(e), an inorganic insulating layer 17 is formed so as to cover the oxide semiconductor layer 15, the source electrode 11s, and the like. The inorganic insulating layer 17 has a multilayer structure in which an SiO₂ layer having a thickness of 300 nm and an SiNx layer having a thickness of 100 nm are stacked in this order, for example. In the inorganic insulating layer 17, contact holes 17a are formed by using a photolithography process, so as to expose drain regions of the oxide semiconductor layer 15.

Then, as shown in FIG. 6(a), a transparent electrically conductive film is deposited on the inorganic insulating layer 17, and this transparent electrically conductive film is patterned by using a photolithography process, thereby forming pixel electrodes 12 and drain electrodes 11d. The pixel electrodes 12 and the drain electrodes 11d are, an IZO layer having a thickness of 100 nm, for example.

Next, as shown in FIG. 6(b), a dielectric layer 18 is formed so as to cover the pixel electrodes 12 and the drain electrodes 11d. The dielectric layer 18 is an SiNx layer having a thickness of 100 nm, for example.

Then, as shown in FIG. 6(c), a transparent electrically conductive film is deposited on the dielectric layer 18, and this transparent electrically conductive film is patterned by using a photolithography process, thereby forming a common electrode 19 having slits 19a. The common electrode 19 is an IZO layer having a thickness of 100 nm, for example. Thereafter, an alignment film is formed over the entire surface so as to cover the common electrode 19, whereby the TFT substrate 10 is obtained.

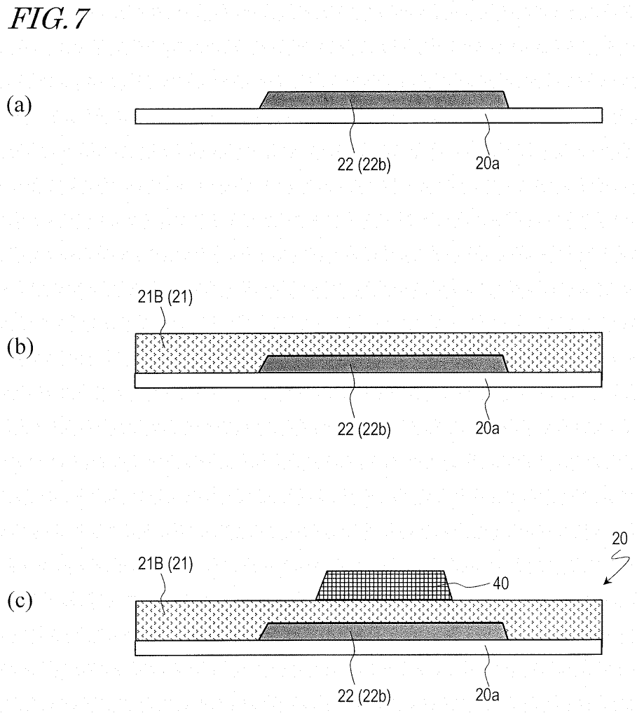

Next, with reference to FIG. 7, a method of producing the counter substrate 20 will be described. FIGS. 7(a) through (c) are step-by-step cross-sectional views illustrating production steps of the counter substrate 20, showing a cross section corresponding to FIG. 2.

First, as shown in FIG. 7(a), a light shielding film is deposited on a transparent substrate (e.g., a glass substrate) 20a, and this light shielding film is patterned by using a photolithography process, thereby forming a light shielding layer 22 including first light shielding portions 22a and second light shielding portions 22b. The light shielding layer 22 is a light-shielding resin layer having a thickness of 1000 nm, for example. Note that the material of the light shielding layer 21 is not limited to a resin material, but may be a metal material having low reflectance.

Next, as shown in FIG. 7(b), red color filters, green color filters, and blue color filters are sequentially formed in regions corresponding to red pixels R, green pixels G, and blue pixels B, thereby forming a color filter layer 21. As the materials of the red color filters, the green color filters, and the blue color filters, colored photosensitive resin materials may be used, for example.

Then, as shown in FIG. 7(c), a plurality of columnar spacers 40 are formed so as to overlap the second light shielding portions 22b. The plurality of columnar spacers 40 are made of a photosensitive resin material, for example. Thereafter, an alignment film is formed over the entire surface, whereby the counter substrate 20 is obtained.

By attaching together the TFT substrate 10 and the counter substrate 20 produced in the aforementioned manners, and injecting a liquid crystal material in the gap between them, a liquid crystal layer 30 is formed. Thereafter, the resultant structure is split into individual panels, whereby the liquid crystal display device 100 is completed.

### Embodiment 2

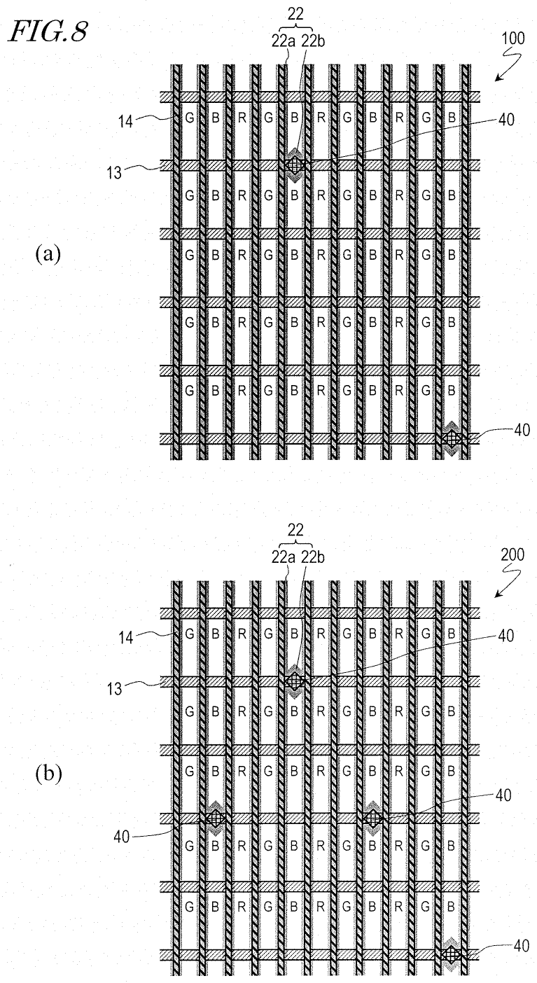

With reference to FIGS. 8(a) and (b), a liquid crystal display device 200 according to the present embodiment will be described in comparison with the liquid crystal display device 100 of Embodiment 1. FIGS. 8(a) and (b) are plan views schematically showing the liquid crystal display devices 100 and 200, respectively.

The pixel structure of the liquid crystal display device 200 of the present embodiment is substantially identical to the pixel structure of the liquid crystal display device 100 of Embodiment 1, and the description thereof is omitted here. In the liquid crystal display device 200 of the present embodiment, too, the plurality of columnar spacers 40 are placed only in a subset of blue pixels B. However, as can be seen from a comparison between FIGS. 8(a) and (b), in the present embodiment, the number of plural columnar spacers 40 is greater than the number of plural columnar spacers 40 in the liquid crystal display device 100 of Embodiment 1. In other words, in the present embodiment, the columnar spacers 40 have a higher density of placement than in Embodiment 1.

As has already been described, any method of use where the liquid crystal panel would be pressed does not need to be considered in a head-mounted display; however, if the pressure resistance is extremely low, insufficiencies may be caused during the production steps. As in the present embodiment, by slightly increasing the number of plural spacers 40 (i.e., so that the density of placement of the columnar spacers 40 is higher than the density of placement of main spacers in a conventionally-available generic liquid crystal display device), insufficiencies caused by low pressure resistance can be suppressed.

Note that, if the density of placement of the columnar spacers 40 is made too high, the aperture ratio will of course be degraded considerably. The density of placement of the columnar spacers 40 is preferably equal to or less than 10 times the density of placement of conventional main spacers, and specifically, e.g., more than 12 pieces/mm² but not more than 120 pieces/mm².

### Embodiment 3

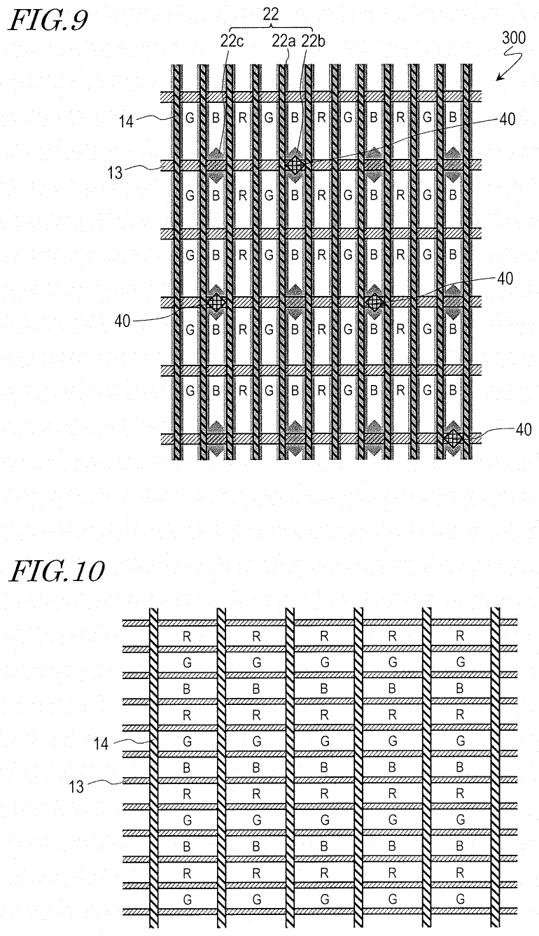

With reference to FIG. 9, a liquid crystal display device 300 according to the present embodiment will be described. FIG. 9 is a plan view schematically showing the liquid crystal display device 300. The pixel structure of the liquid crystal display device 300 of the present embodiment is substantially identical to the pixel structure of the liquid crystal display devices 100 and 200 of Embodiments 1 and 2, and the description thereof is omitted here.

As shown in FIG. 9, the light shielding layer 22 of the liquid crystal display device 300 includes not only the first light shielding portions 22a and the second light shielding portions 22b, but also third light shielding portions 22c. The third light shielding portions 22c are substantially identical in shape to the second light shielding portions 22b. However, the third light shielding portions 22c do not overlap the plurality of columnar spacers 40.

In the present embodiment, as will be described below, the second light shielding portions 22b and the third light shielding portions 22c of the light shielding layer 22 are placed so that the aperture ratios of the plurality of blue pixels B (i.e., all blue pixels B in the display region) are substantially equal.

As shown in FIG. 9, each second light shielding portions 22b is formed astride two blue pixels B which adjoin each other along the column direction. Similarly, each third light shielding portion 22c is formed astride two blue pixels B which adjoin each other along the column direction. At an upper end portion and a lower end portion (one end portion or another end portion along the column direction) of each blue pixel B, either a second light shielding portion 22b or a third light shielding portion 22c is located.

In the liquid crystal display device 300 of the present embodiment, with the aforementioned construction, those blue pixels B in which the columnar spacers 40 are placed can be prevented from being perceived as being darker than the other blue pixels B, with greater certainty. As has been described with reference to FIG. 4, by ensuring that a decrease in aperture ratio ascribable to the second light shielding portions 22b is 30% or less, those blue pixels B in which the columnar spacers 40 are placed can be restrained from being perceived as being dark; however, it is not to say that there will be absolutely no person who will have such perception (in the example shown in FIG. 4, one person has the perception even if the decrease in aperture ratio is 25%).

On the other hand, in the present embodiment, the light shielding portion 22 includes the third light shielding portions 22c, the aperture ratios of all blue pixels B are substantially equal, so that those blue pixels B in which the columnar spacers 40 are placed will not be perceived as being darker than the other blue pixels B.

In the liquid crystal display device 300 of the present embodiment, the aperture ratio of the blue pixels B will be lower than the aperture ratios of the red pixels R and the green pixels G. Therefore, if a color filter layer 21 that was designed on the premise that the red pixels R, the green pixels G, and the blue pixels B all have the same aperture ratio is straightforwardly used, the displayed color may possibly become yellowish (i.e., the coloration may be shifted in the yellow direction). Therefore, it is preferable to use a color filter layer 21 that was designed by taking it into account the aperture ratio of the blue pixels B being lower than the aperture ratios of the red pixels R and the green pixels G.

[Lateral Stripe Arrangement]

FIG. 1 and the like illustrate a so-called “vertical stripe arrangement” in which the red pixel columns, the green pixel columns, and the blue pixel columns are defined; however, embodiments of the present invention may be directed to liquid crystal display devices of a so-called “lateral stripe arrangement”.

FIG. 10 shows a pixel arrangement for a liquid crystal display device of a lateral stripe arrangement. As shown in FIG. 10, the plurality of pixels are arranged so that a plurality of red pixel rows extending along the row direction, a plurality of green pixel rows extending along the row direction, and a plurality of blue pixel rows extending along the row direction are defined.

In a lateral stripe arrangement, a gate bus line 13 exists between pixels of different colors. Therefore, when the construction of the present embodiment is employed in a lateral stripe arrangement, the first light shielding portions 22a of the light shielding layer 22 are to be placed so as to overlap not the source bus lines 14 but the gate bus lines 13.

[Regarding Oxide Semiconductor]

The oxide semiconductor contained in the oxide semiconductor layer 15 may be an amorphous oxide semiconductor, or a crystalline oxide semiconductor having a crystalline portion. Examples of crystalline oxide semiconductors include polycrystalline oxide semiconductors, microcrystalline oxide semiconductors, crystalline oxide semiconductors whose c axis is oriented essentially perpendicular to the layer plane, and so on.

The oxide semiconductor layer 15 may have a multilayer structure of two or more layers. When the oxide semiconductor layer 15 has a multilayer structure, the oxide semiconductor layer 15 may include an amorphous oxide semiconductor layer and a crystalline oxide semiconductor layer, include a plurality of crystalline oxide semiconductor layers of different crystal structures, or include a plurality of amorphous oxide semiconductor layers. In the case where the oxide semiconductor layer 15 has a two-layer structure including an upper layer and a lower layer, the energy gap of the oxide semiconductor that is contained in the upper layer is preferably greater than the energy gap of the oxide semiconductor that is contained in the lower layer. However, when the difference between the energy gaps of these layers is relatively small, the energy gap of the oxide semiconductor of the lower layer may be greater than the energy gap of the oxide semiconductor of the upper layer.

The material, structure, and method of film formation of an amorphous oxide semiconductor and each above crystalline oxide semiconductor, the construction of an oxide semiconductor layer having multilayer structure, etc., are described in Japanese Laid-Open Patent Publication No. 2014-007399, for example. The entire disclosure of Japanese Laid-Open Patent Publication No. 2014-007399 is incorporated herein by reference.

The oxide semiconductor layer 15 may contain at least one metallic element among In, Ga, and Zn, for example. In an embodiment of the present invention, the oxide semiconductor layer 15 contains an In—Ga—Zn—O based semiconductor (e.g. indium gallium zinc oxide), for example. Herein, the In—Ga—Zn—O based semiconductor is a ternary oxide of In (indium), Ga (gallium), Zn (zinc). The ratio between In, Ga, and Zn (composition ratio) is not particularly limited, and includes In:Ga:Zn=2:2:1, In:Ga:Zn=1:1:1, In:Ga:Zn=1:1:2, and the like, for example. Such an oxide semiconductor layer 2a may be made from an oxide semiconductor film containing an In—Ga—Zn—O based semiconductor.

The In—Ga—Zn—O based semiconductor may be amorphous or crystalline. As the crystalline In—Ga—Zn—O based semiconductor, a crystalline In—Ga—Zn—O based semiconductor whose c axis is oriented essentially perpendicular to the layer plane is preferable.

Note that the crystal structure of a crystalline In—Ga—Zn—O based semiconductor is disclosed in, for example, Japanese Laid-Open Patent Publication No. 2014-007399, supra, Japanese Laid-Open Patent Publication No. 2012-134475, Japanese Laid-Open Patent Publication No. 2014-209727, and so on. The entire disclosures of Japanese Laid-Open Patent Publication No. 2012-134475 and Japanese Laid-Open Patent Publication No. 2014-209727 are incorporated herein by reference. A TFT including an In—Ga—Zn—O based semiconductor layer has a high mobility (20 times that of an a-Si TFT or greater) and a low leakage current (less than 1/100 times that of an a-Si TFT), and therefore is suitably used as a driving TFT (e.g., a TFT that is included in a driving circuit which is provided on the same substrate as the display region, near a display region including a plurality of pixels) or as a pixel TFT (a TFT that is provided in a pixel).

Instead of an In—Ga—Zn—O based semiconductor, the oxide semiconductor layer 15 may contain any other oxide semiconductor. For example, it may contain an In—Sn—Zn—O based semiconductor (e.g. In₂O₃—SnO₂—ZnO; InSnZnO). An In—Sn—Zn—O based semiconductor is a ternary oxide of In (indium), Sn (tin), and Zn (zinc). Alternatively, the oxide semiconductor layer 2a may contain an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, a CdO (cadmium oxide), an Mg—Zn—O based semiconductor, an In—Ga—Sn—O based semiconductor, an In—Ga—O based semiconductor, a Zr—In—Zn—O based semiconductor, an Hf—In—Zn—O based semiconductor, or the like.

Note that the TFTs 2 being oxide semiconductor TFTs may be “channel-etch type TFTs”, or “etchstop type TFTs”.

In a channel-etch type TFT, no etchstop layer is formed in the channel region, and thus the lower faces of the ends of the source and drain electrodes that are closer to the channel are disposed in contact with the upper face of the oxide semiconductor layer. A channel-etch type TFT is formed by, for example, forming an electrically conductive film for the source/drain electrodes on the oxide semiconductor layer, and effecting source-drain separation. In the source-drain separation step, a surface portion of the channel region may become etched in some cases.

On the other hand, in a TFT having an etchstop layer formed above the channel region (etchstop type TFT), the lower faces of the ends of the source and drain electrodes that are closer to the channel may be located above the etchstop layer, for example. An etchstop type TFT is formed by, for example, after forming an etchstop layer that covers a portion of the oxide semiconductor layer to become a channel region, forming an electrically conductive film for the source/drain electrodes upon the oxide semiconductor layer and the etchstop layer, and effecting source-drain separation.

[Other Constructions for TFT Substrate]

Hereinafter, with reference to the drawings, another TFT substrate for use in a liquid crystal display device according to an embodiment of the present invention will be described. The TFT substrate described herein is an active matrix substrate having oxide semiconductor TFTs and crystalline silicon TFTs which are formed on the same substrate.

The active matrix substrate includes a TFT (pixel TFT) for each pixel. As the pixel TFTs, oxide semiconductor TFTs whose active layer is an In—Ga—Zn—O based semiconductor film are used, for example.

In some cases, a part or a whole of a peripheral driving circuit may be integrally formed on the same substrate as the pixel TFTs. Such an active matrix substrate is referred to as a driver-monolithic active matrix substrate. In a driver-monolithic active matrix substrate, the peripheral driving circuit is to be provided in a region (a non-display region or a frame region) other than the region that contains a plurality of pixels (display region). As the TFTs composing the peripheral driving circuit (circuit TFTs), crystalline silicon TFTs whose active layer is a polycrystalline silicon film are used, for example. Thus, by using oxide semiconductor TFTs as the pixel TFTs, and crystalline silicon TFTs as the circuit TFTs, power consumption can be reduced in the display region, while the frame region can be made smaller.

Next, a more specific construction of an active matrix substrate having oxide semiconductor TFTs and crystalline silicon TFTs will be described with reference to the drawings.

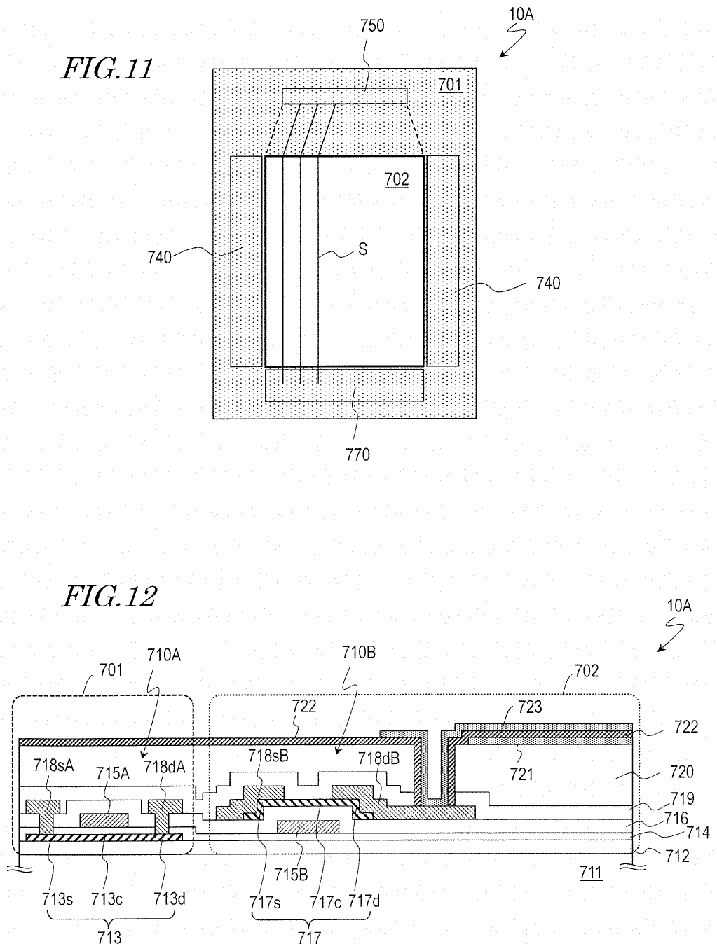

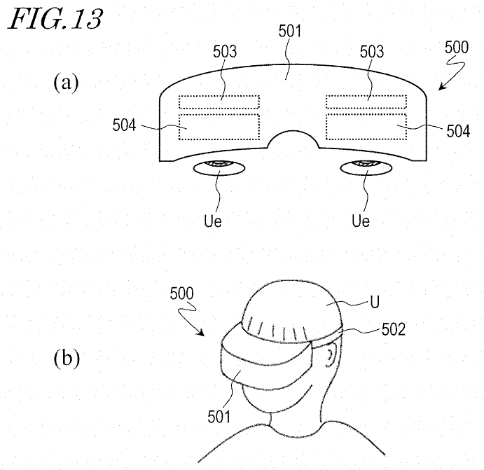

FIG. 11 is a schematic plan view showing an exemplary planar structure of a TFT substrate 10A. FIG. 12 is a cross-sectional view of a crystalline silicon TFT (hereinafter referred to as the “first thin film transistor”) 710A and an oxide semiconductor TFT (hereinafter referred to as the “second thin film transistor”) 710B in the TFT substrate 10A.

As shown in FIG. 11, the TFT substrate 10A has a display region 702 including a plurality of pixels and a region (non-display region) other than the display region 702. The non-display region includes a driving circuit forming region 701 in which driving circuitry is provided. In the driving circuit forming region 701, gate driver circuits 740, a check circuit 770, and the like are provided, for example. In the display region 702, a plurality of gate bus lines (not shown) extending along the row direction and a plurality of source bus lines S extending along the column direction are formed. Although not shown, each pixel is defined by a gate bus line and a source bus line S, for example. The gate bus lines are respectively connected to the terminals of the gate driver circuits. The source bus lines S are respectively connected to the terminals of a driver IC 750 that is mounted on the active matrix substrate 700.

As shown in FIG. 12, in the TFT substrate 10A, a second thin film transistor 710B is formed as a pixel TFT for each pixel in the display region 702, whereas first thin film transistors 710A are formed as circuit TFTs in the driving circuit forming region 701.

The TFT substrate 10A includes a substrate 711, an underlying film 712 formed on the surface of the substrate 711, a first thin film transistor 710A formed on the underlying film 712, and a second thin film transistor 710B formed on the underlying film 712. The first thin film transistor 710A is a crystalline silicon TFT having an active region that mainly contains crystalline silicon. The second thin film transistor 710B is an oxide semiconductor TFT having an active region that mainly contains an oxide semiconductor. The first thin film transistor 710A and the second thin film transistor 710B are fabricated in an integral manner into the substrate 711. As used herein, within the semiconductor layer to become an active layer of a TFT, an “active region” refers to a region where a channel is to be formed.

The first thin film transistor 710A includes a crystalline silicon semiconductor layer (e.g., a low-temperature polysilicon layer) 713 formed on the underlying film 712, a first insulating layer 714 covering the crystalline silicon semiconductor layer 713, and a gate electrode 715A provided on the first insulating layer 714. The portion of the first insulating layer 714 that is located between the crystalline silicon semiconductor layer 713 and the gate electrode 715A functions as a gate insulating film of the first thin film transistor 710A. The crystalline silicon semiconductor layer 713 has a region (active region) 713c in which a channel is to be formed, and a source region 713s and a drain region 713d respectively located on opposite sides of the active region. In this example, a portion of the crystalline silicon semiconductor layer 713 that overlaps the gate electrode 715A via the first insulating layer 714 defines the active region 713c. The first thin film transistor 710A also includes a source electrode 718sA and a drain electrode 718dA which are respectively connected to the source region 713s and the drain region 713d. The source and drain electrodes 718sA and 718dA may be provided on an interlevel dielectric film (which herein is a second insulating layer 716) covering the gate electrode 715A and the crystalline silicon semiconductor layer 713, and connected to the crystalline silicon semiconductor layer 713 within contact holes which are formed in the interlevel dielectric film.

The second thin film transistor 710B includes a gate electrode 715B provided on the underlying film 712, a second insulating layer 716 covering the gate electrode 715B, and an oxide semiconductor layer 717 on the second insulating layer 716. As shown in the figure, the first insulating layer 714, which is the gate insulating film of the first thin film transistor 710A, may extend to the region where the second thin film transistor 710B is to be formed. In this case, the oxide semiconductor layer 717 may be formed on the first insulating layer 714. A portion of the second insulating layer 716 that is located between the gate electrode 715B and the oxide semiconductor layer 717 functions as a gate insulating film of the second thin film transistor 710B. The oxide semiconductor layer 717 has a region (active region) 717c in which a channel is to be formed, and a source contact region 717s and a drain contact region 717d respectively located on opposite sides of the active region. In this example, a portion of the oxide semiconductor layer 717 that overlaps the gate electrode 715B via the second insulating layer 716 defines the active region 717c. Moreover, the second thin film transistor 710B further includes a source electrode 718sB and a drain electrode 718dB which are respectively connected to the source contact region 717s and the drain contact region 717d. Note that a construction in which no underlying film 712 is formed on the substrate 711 would also be possible.

The thin film transistors 710A and 710B are covered by a passivation film 719 and a planarization film 720. In each second thin film transistor 710B functioning as a pixel TFT, the gate electrode 715B is connected to a gate bus line (not shown), the source electrode 718sB is connected to a source bus line (not shown), and the drain electrode 718dB is connected to the pixel electrode 723. In this example, the drain electrode 718dB is connected to the corresponding pixel electrode 723 within an opening which is formed in the passivation film 719 and the planarization film 720. A video signal is supplied to the source electrode 718sB via the source bus line, and a necessary charge is written to the pixel electrode 723 based on a gate signal from the gate bus line.

As shown in the figure, a transparent conductive layer 721 may be formed as a common electrode on the planarization film 720, and a third dielectric layer 22 may be formed between the transparent conductive layer (common electrode) 721 and the pixel electrodes 723. In this case, the pixel electrodes 723 may have slit apertures. The TFT substrate 10A as such may be applicable to a display device of an FFS mode, for example. An FFS mode is a mode under the lateral field method, in which a pair of electrodes are provided on one substrate and an electric field is applied to liquid crystal molecules in a direction (lateral direction) that is parallel to the substrate plane. In this example, an electric field is created as represented by electric lines of force which go out from the pixel electrode 723, pass through the liquid crystal layer (not shown), and further through the slit apertures in the pixel electrode 723 to emerge on the common electrode 721. This electric field includes a component in a lateral direction to the liquid crystal layer. As a result, an electric field in the lateral direction can be applied to the liquid crystal layer. In the lateral field method, liquid crystal molecules do not erect from the substrate, thus providing an advantage of being able to provide a wider viewing angle than in the vertical field method.

As a TFT (check TFT) in the check circuit 770 shown in FIG. 11, the thin film transistor 710B, which is an oxide semiconductor TFT, may be used.

Although not shown, the check TFT(s) and the check circuit may be formed in the region where the driver IC 750 shown in FIG. 11 is mounted, for example. In this case, the check TFT is interposed between the driver IC 750 and the substrate 711.

In the example shown in the figure, the first thin film transistor 710A has a top gate structure in which the crystalline silicon semiconductor layer 713 is disposed between the gate electrode 715A and the substrate 711 (the underlying film 712). On the other hand, the second thin film transistor 710B has a bottom gate structure in which the gate electrode 715B is disposed between the oxide semiconductor layer 717 and the substrate 711 (the underlying film 712). By adopting such a structure, when forming the two types of thin film transistors 710A and 710B in an integral manner on the same substrate 711, it is possible to more effectively suppress increase in the number of production steps and the production cost.

The TFT structures of the first thin film transistor 710A and the second thin film transistor 710B are not limited to the above. For example, the thin film transistors 710A and 710B may have the same TFT structure. Alternatively, the first thin film transistor 710A may have a bottom gate structure while the second thin film transistor 710B may have a top gate structure. In the case of a bottom-gate structure, it may be of the channel-etch type as is the thin film transistor 710B, or of the etchstop type. Moreover, it may be of a bottom contact type where the source electrode and the drain electrode are located below the semiconductor layer.

The second insulating layer 716, which is the gate insulating film of the second thin film transistor 710B, may be allowed to extend to the region where the first thin film transistor 710A is formed, so as to function as an interlevel dielectric film covering the gate electrode 715A and the crystalline silicon semiconductor layer 713 of the first thin film transistor 710A. When the interlevel dielectric film of the first thin film transistor 710A and the gate insulating film of the second thin film transistor 710B are thus formed in the same layer (second dielectric layer) 716, the second insulating layer 716 may have a multilayer structure. For example, the second insulating layer 716 may have a multilayer structure that includes a hydrogen donor layer (e.g., a silicon nitride layer) capable of supplying hydrogen and an oxygen donor layer (e.g., a silicon oxide layer) capable of supplying oxygen and disposed on the hydrogen donor layer.

The gate electrode 715A of the first thin film transistor 710A and the gate electrode 715B of the second thin film transistor 710B may be formed in the same layer. Moreover, the source and drain electrodes 718sA and 718dA of the first thin film transistor 710A and the source and drain electrodes 718sB and 718dB of the second thin film transistor 710B may be formed in the same layer. Being “formed in the same layer” means being formed by using the same film (conductive film). As a result, increase in the number of production steps and the production cost can be suppressed.

[Head-Mounted Display]

The liquid crystal display devices 100, 200 and 300 according to embodiments of the present invention are suitably used for head-mounted displays (HMD). An example of an HMD is shown in FIGS. 13(a) and (b). FIG. 13(a) is a diagram showing a schematic construction of the HMD 500, and FIG. 13(b) is a diagram showing how the HMD 500 may be worn by a user U.

As shown in FIGS. 13(a) and (b), the HMD 500 includes a housing 501, a band 502, a display section 503, and optics 504. The housing 501 accommodates the display section 503 and the optics 504 inside. The band 502 is attached to both of the right and left ends of the housing 501. The band 502 allows the HMD 500, including the housing 501, to be fixed (worn) on the head of the user U.

The display section 503 is placed so as to be in front of both eyes Ue of the user U when the HMD 500 is worn. The display section 503 includes a liquid crystal display device to display images. The optics 504 is located between the display section 503 and both eyes Ue of the user U. Via the optics 504, the user U observes an image that is displayed on the liquid crystal display device of the display section 503.

As the liquid crystal display device to be included in the display section 503, the liquid crystal display device 100, 200 or 300 according to an embodiment of the present invention can be suitably used. Note that the HMD construction in which a liquid crystal display device according to an embodiment of the present invention is used is not to be limited to what is illustrated in FIGS. 13(a) and (b).

### INDUSTRIAL APPLICABILITY

According to an embodiment of the present invention, the aperture ratio of a liquid crystal display device that includes oxide semiconductor TFTs can be improved. A liquid crystal display device according to an embodiment of the present invention may have a high aperture ratio, and therefore is suitably used for a head-mounted display.

### REFERENCE SIGNS LIST

10, 10A active matrix substrate (TFT substrate)

10a insulative substrate

11 thin film transistor (TFT)

11g gate electrode

11s source electrode

11d drain electrode

12 pixel electrode

13 gate bus line (scanning line)

14 source bus line (signal line)

15 oxide semiconductor layer

16 gate insulating layer

17 inorganic insulating layer

17a contact hole

18 dielectric layer

19 common electrode

19a slit

20 counter substrate (color filter substrate)

20a insulative substrate

21 color filter layer

21B blue color filter

22 light shielding layer (black matrix)

22a first light shielding portion

22b second light shielding portion

22c third light shielding portion

30 liquid crystal layer

40 columnar spacer

100, 200, 300 liquid crystal display device

500 head-mounted display

501 housing

502 band

503 display section

504 optics

R red pixel

G green pixel

B blue pixel

1. A liquid crystal display device for head-mounted displays comprising:
a first substrate;
a second substrate opposing the first substrate;
a liquid crystal layer provided between the first substrate and the second substrate; and
a plurality of columnar spacers provided between the first substrate and the second substrate, the plurality of columnar spacers defining a thickness of the liquid crystal layer,
the liquid crystal display device having a plurality of pixels arranged in a matrix array including a plurality of rows and a plurality of columns, wherein,
the plurality of pixels include a plurality of red pixels, a plurality of green pixels, and a plurality of blue pixels;
the first substrate has a thin film transistor provided in each of the plurality of pixels, a plurality of gate bus lines extending along one of a row direction and a column direction, and a plurality of source bus lines extending along another of the row direction and the column direction;
each thin film transistor includes an oxide semiconductor layer;
each of the plurality of columnar spacers is in contact with both of the first substrate and the second substrate, such that the plurality of columnar spacers do not include any columnar spacers that are in contact with only one of the first substrate and the second substrate;
the second substrate includes a light shielding layer, the light shielding layer including first light shielding portions respectively overlapping the plurality of gate bus lines or the plurality of source bus lines, and a second light shielding portions respectively overlapping the plurality of columnar spacers;
each of the plurality of columnar spacers is placed in one of the plurality of blue pixels; and
the second light shielding portions of the light shielding layer are placed so that, in those blue pixels in which the second light shielding portions exist, a decrease in aperture ratio ascribable to the second light shielding portions is 30% or less.

2. The liquid crystal display device of claim 1, wherein the plurality of columnar spacers are placed in a subset of blue pixels among the plurality of blue pixels.

3. The liquid crystal display device of claim 2, wherein the plurality of columnar spacers are placed so as to overlap the thin film transistors in the subset of blue pixels.

4. The liquid crystal display device of claim 2, wherein the light shielding layer further includes third light shielding portions that are substantially identical in shape to the second light shielding portions, the third light shielding portions not overlapping the plurality of columnar spacers.

5. The liquid crystal display device of claim 4, wherein the second light shielding portions and the third light shielding portions of the light shielding layer are placed so that the plurality of blue pixels have substantially a same aperture ratio.

6. The liquid crystal display device of claim 4, wherein,
the plurality of gate bus lines extend along the row direction;
the plurality of source bus lines extend along the column direction;
the first light shielding portions respectively overlap the plurality of source bus lines;
the plurality of pixels are arranged so that a plurality of red pixel columns extending along the column direction, a plurality of green pixel columns extending along the column direction, and a plurality of blue pixel columns extending along the column direction are defined;
each of the second light shielding portions and the third light shielding portions is formed astride two blue pixels which adjoin each other along the column direction; and
either the respective second light shielding portion or the respective third light shielding portion is located at one end portion or another end portion of each of the plurality of blue pixels along the column direction.

7. The liquid crystal display device of claim 1, wherein a density of placement of the plurality of columnar spacers is not more than 12 pieces/mm².

8. The liquid crystal display device of claim 1, wherein a density of placement of the plurality of columnar spacers is more than 12 pieces/mm² but not more than 120 pieces/mm².

9. The liquid crystal display device of claim 1, wherein,
the first substrate further includes a pixel electrode provided in each of the plurality of pixels, the pixel electrode being electrically connected to a drain electrode of the thin film transistor; and
the drain electrode is a transparent drain electrode being made of a same transparent electrically conductive film as the pixel electrode and extending from the pixel electrode.

10. The liquid crystal display device of claim 1, wherein,
the first substrate includes an inorganic insulating layer at least covering the oxide semiconductor layers of the thin film transistors; and
the first substrate does not include an organic insulating layer between the inorganic insulating layer and the pixel electrodes.

11. The liquid crystal display device of claim 1, wherein the oxide semiconductor layer comprises an In—Ga—Zn—O based semiconductor.

12. The liquid crystal display device of claim 11, wherein the In—Ga—Zn—O based semiconductor includes a crystalline portion.

13. A head-mounted display comprising a display section placed so as to be in front of both eyes of a user when worn, wherein
the display section includes the liquid crystal display device of claim 1.
